(19) United States
(12) Patent Application Publication
(10) Pub. No.: US 2007/0212569 A1
(43) Pub. Date: Sep. 13, 2007

(54) ORGANOMETALLIC COMPLEX FOR ORGANIC LIGHT-EMITTING LAYER AND ORGANIC LIGHT-EMITTING DIODE USING THE SAME

(76) Inventors: Jong-Tae Je, Cheongju-si (KR); Dong-Soo Lim, Cheongju-si (KR); Seon-Keun Yoo, Jeungpyeong-gun (KR); Jai-Sang Yoon, Iksan-si (KR)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/683,403

(22) Filed: Mar. 7, 2007

(30) Foreign Application Priority Data
Mar. 7, 2006 (KR) 10-2006-0021278
Feb. 28, 2007 (KR) 10-2007-0020638

(51) Int. Cl. H01L 51/54; C09K 11/06

(52) U.S. Cl. 428/690; 428/917; 313/504; 313/506; 257/E51.043; 257/E51.044; 546/7

(57) ABSTRACT

An organometallic complex for an organic light-emitting layer and an organic light-emitting diode are provided. A naphthalene derivative as a ligand is introduced to the organometallic complex. The organic light-emitting diode uses the organometallic complex as a phosphorescent host material. The organic light-emitting diode exhibits high current efficiency, high power efficiency and long lifetime when compared to conventional devices using BAlq.

### BACKGROUND OF THE INVENTION

1. Field of the Invention

The present invention relates to an organometallic complex for an organic light-emitting layer. More specifically, the present invention relates to an organometallic complex for an organic light-emitting layer that can be used to fabricate an organic light-emitting diode with high efficiency and long lifetime, and an organic light-emitting diode with high efficiency and long lifetime using the organometallic complex.

2. Description of the Related Art

As displays have become larger in size in recent years, there is an increasing demand for flat panel display devices that take up as little space as possible. Liquid crystal display devices as representative flat panel display devices can be reduced in weight when compared to the prior art cathode ray tubes (CRTs), but have several disadvantages in that the viewing angle is limited, the use of back light is inevitably required, etc. Organic light-emitting diodes (OLEDs) as a novel type of flat panel display devices are self-emissive display devices. Organic light-emitting diodes have a large viewing angle, and are advantageous in terms of light weight, small thickness, small size and rapid response time when compared to liquid crystal display devices.

A representative organic light-emitting diode was reported by Gurnee in 1969 (U.S. Pat. Nos. 3,172,862 and 3,173,050). However, this organic light-emitting diode suffers from limitations in its applications because of its limited performance. Since Eastman Kodak Co. reported multilayer organic light-emitting diodes in 1987 (C. W. Tang et al., Appl. Phys. Lett., 51, 913 (1987); and J. Applied Phys., 65, 3610 (1989)), remarkable progress has been made in the development of organic light-emitting diodes capable of overcoming the problems of the prior art devices. Organic light-emitting diodes have superior characteristics, such as low driving voltage (e.g., 10V or less), broad viewing angle, rapid response time and high contrast, over plasma display panels (PDPs) and inorganic electroluminescent display devices. Based on these advantages, organic light-emitting diodes can be used as pixels of graphic displays, television image displays and surface light sources. In addition, organic light-emitting diodes can be fabricated on flexible transparent substrates, can be reduced in thickness and weight, and have good color representation. Therefore, organic light-emitting diodes are recognized as promising devices for use in next-generation flat panel displays (FPDS).

Such organic light-emitting diodes comprise a first electrode as a hole injection electrode (anode), a second electrode as an electron injection electrode (cathode), and an organic light-emitting layer disposed between the anode and the cathode wherein electrons injected from the cathode and holes injected from the anode combine with each other in the organic light-emitting layer to form electron-hole pairs (excitons), and then the excitons fall from the excited state to the ground state and decay to emit light. At this time, the excitons may fall from the excited state to the ground state via the singlet excited state to emit light (i.e. fluorescence), or the excitons may fall from the excited state to the ground state via the triplet excited state to emit light (i.e. phosphorescence). In the case of fluorescence, the probability of the singlet excited state is 25% and thus the luminescence efficiency of the devices is limited. In contrast, phosphorescence can utilize both probabilities of the triplet excited state (75%) and the singlet excited state (25%), and thus the theoretical internal quantum efficiency may reach 100%. Several luminescent materials using the triplet excited state have heretofore been known. For example, some phosphorescent materials using iridium or platinum compounds have been reported in Princeton University and University of California, Los Angeles (UCLA) [Sergey Lamansky et al. Inorg. Chem., 40, 1704-1711, 2001 and J. Am. Chem. Soc., 123, 4304-4312, 2001]. In recent years, there has been increasing need for devices with high efficiency and long lifetime required to realize large-area displays. Under these circumstances, much research has been conducted to develop phosphorescent materials and devices using them.

Examples of phosphorescent host materials that are currently in use include 4,4′-N,N′-dicarbazolylbiphenyl (CBP), ((1,1′-biphenyl)-4-olato)bis(2-methyl-8-quinolinolato N1, O8) aluminum (BAlq), and 2,9-dimethyl-4,7-diphenyl-1,10-phenanthroline (BCP). Since BAlq exhibits optimal energy level characteristics and has the ability to transport charges, BAlq is most generally used as a phosphorescent host material, together with CBP, in a device using N,N′-diphenyl-N,N′-bis(1-naphthyl)-1,1′-biphenyl)-4,4′-diamine (NPB) as a hole transport material and Alq₃ as an electron transport material.

U.S. Patent Publication No. 2003/0129452 enumerates aluminum complexes as phosphorescent host materials, and describes that the lifetime of an organic electroluminescence element can be prolonged when the difference in the ionization potential energy between one of the host materials and a hole transport layer is in a range from 0.4 to 0.8 eV. However, the organic electroluminescence element still has the problems that the efficiency is poor and sufficiently long lifetime cannot be ensured.

### SUMMARY OF THE INVENTION

Therefore, it is a first object of the present invention to provide an organometallic complex for an organic light-emitting layer that can be used to fabricate an organic light-emitting diode with high efficiency and long lifetime.

It is a second object of the present invention to provide an organic light-emitting diode with high efficiency and long lifetime comprising the organometallic complex of Formula 1.

In accordance with an aspect of the present invention for achieving the first object, there is provided an organometallic complex for an organic light-emitting layer, represented by Formula 1:

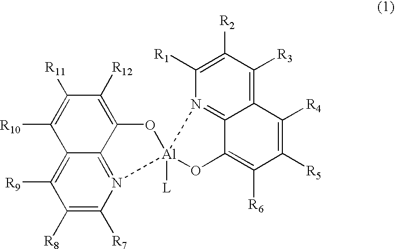

wherein R₁ to R₁₂ are each independently hydrogen, amino, C₁-C₁₀ alkyl, C₁-C₁₀ alkenyl, C₁-C₁₀ alkynyl, or C₁-C₁₀ alkoxy, and

L is 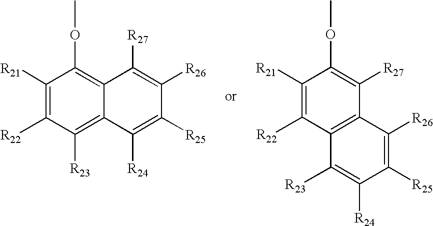
(wherein R₂₁ to R₂₇ are each independently hydrogen, amino, a C₆-C₂₀ aryl group which is unsubstituted or substituted with a group selected from the group consisting of C₁-C₁₀ alkyl, C₁-C₁₀ alkoxy, cyano, C₁-C₁₀ alkylamino, C₁-C₁₀ alkylsilyl, halogen, C₆-C₁₀ aryl, C₆-C₁₀ aryloxy, C₆-C₁₀ arylamino and C₆-C₁₀ arylsilyl, or a C₄-C₁₉ heteroaryl group containing at least one heteroatom selected from N, S and O atoms, with the proviso that at least one group of R₂₁ to R₂₇ is a C₆-C₂₀ aryl group which is unsubstituted or substituted with a group selected from the group consisting of C₁-C₁₀ alkyl, C₁-C₁₀ alkoxy, cyano, C₁-C₁₀ alkylamino, C₁-C₁₀ alkylsilyl, halogen, C₆-C₁₀ aryl, C₆-C₁₀ aryloxy, C₆-C₁₀ arylamino and C₆-C₁₀ arylsilyl, or a C₄-C₁₉ heteroaryl group containing at least one heteroatom selected from N, S and O atoms).

In an embodiment of the present invention, the organometallic complex may be selected from the following compounds:

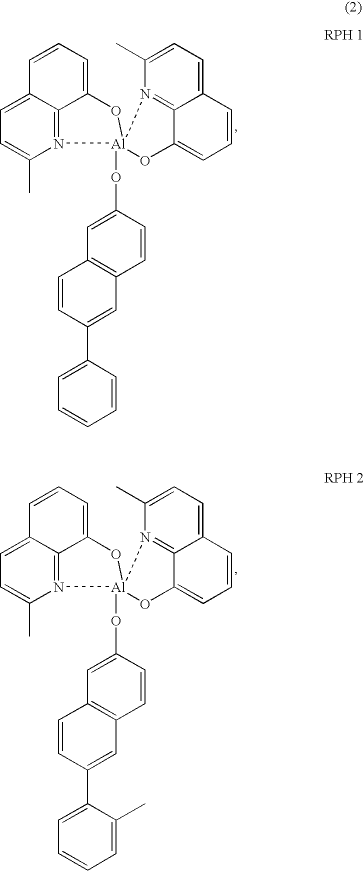

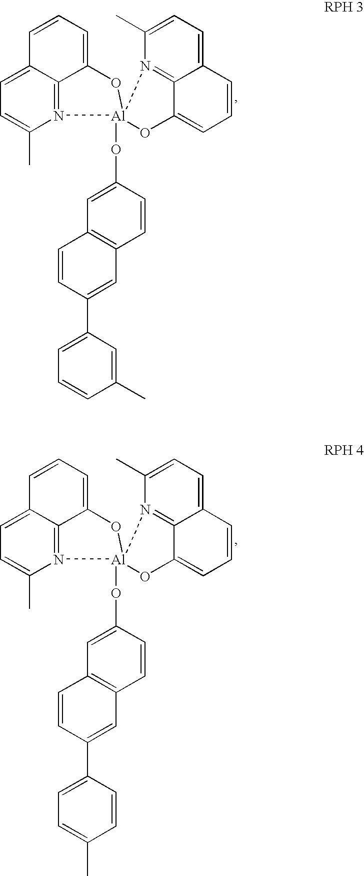

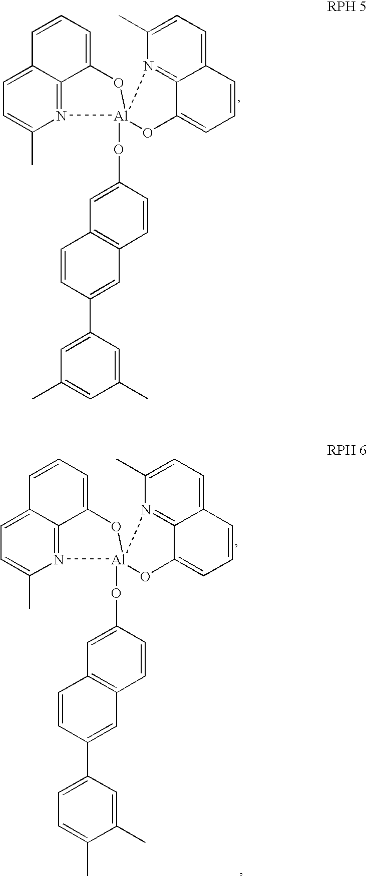

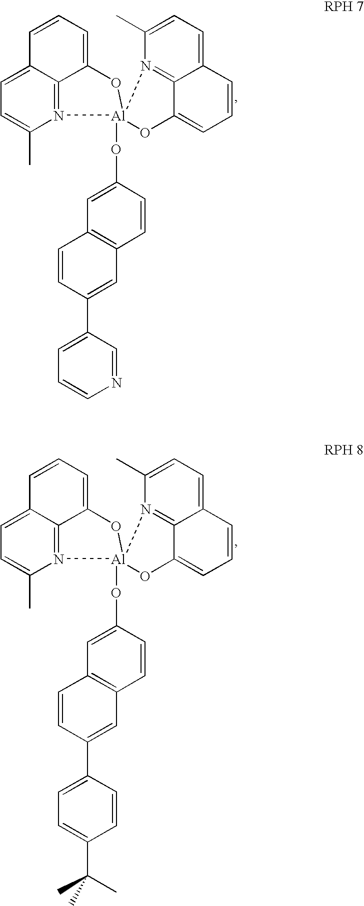

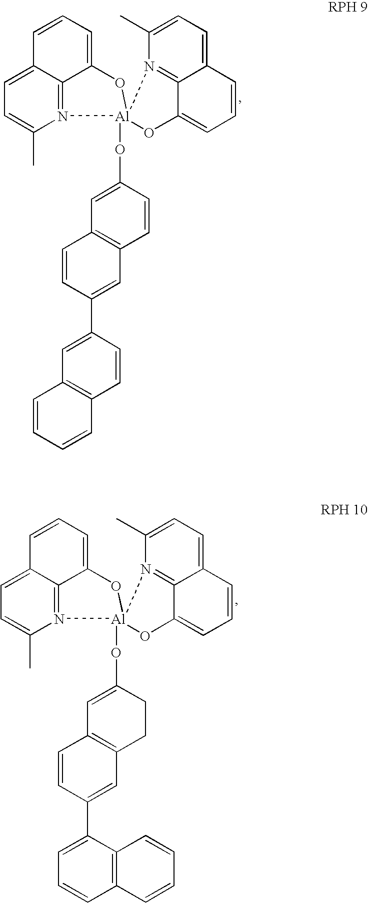

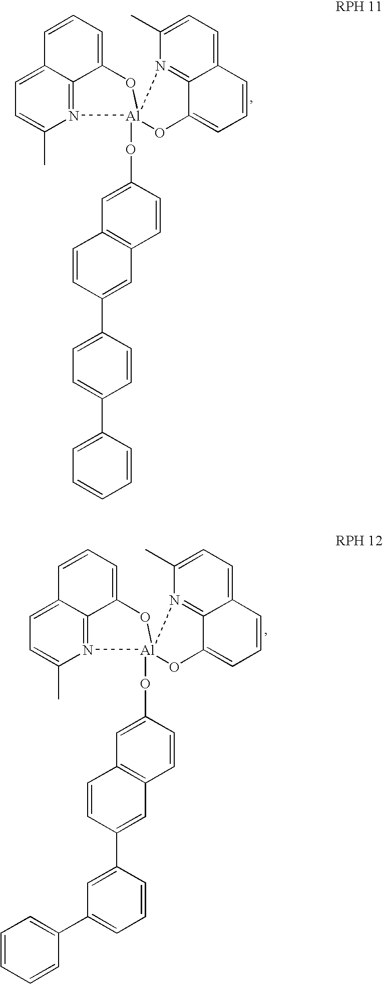

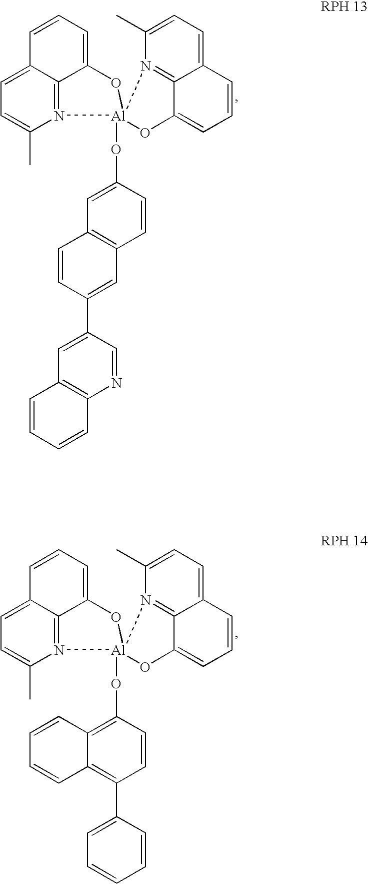

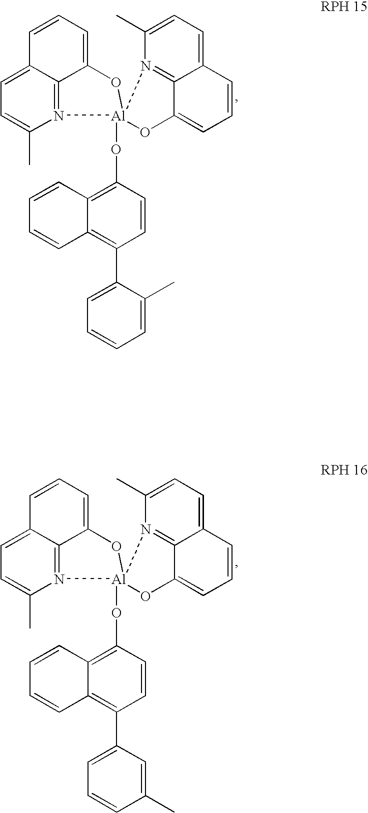

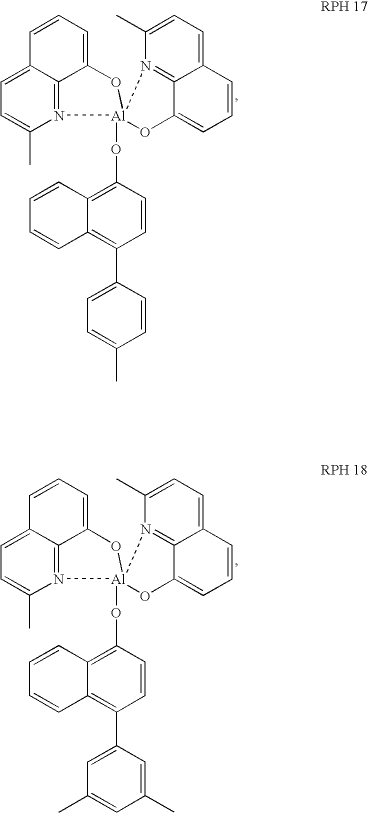

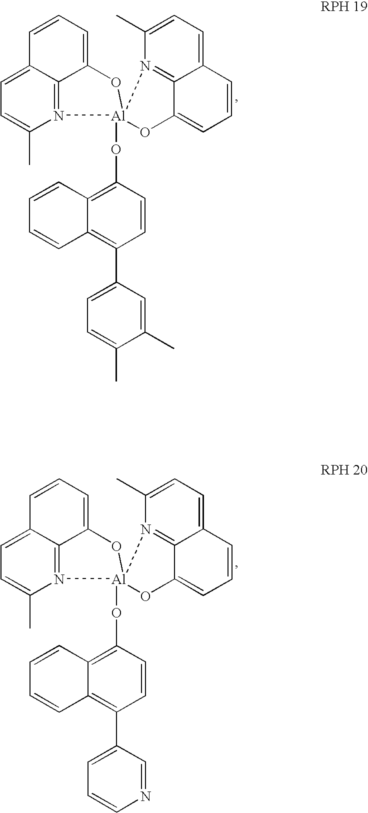

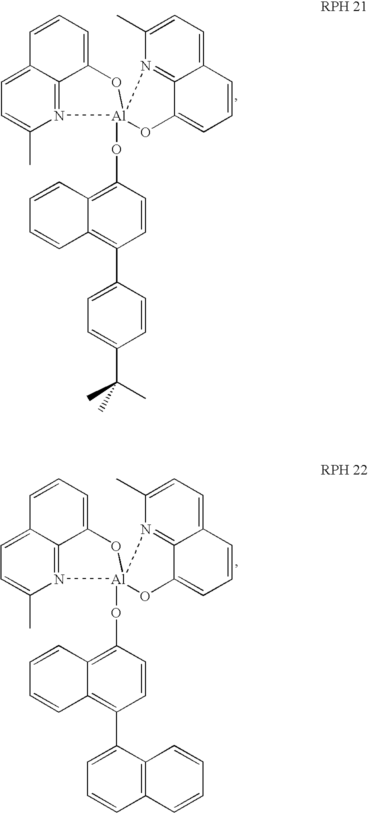

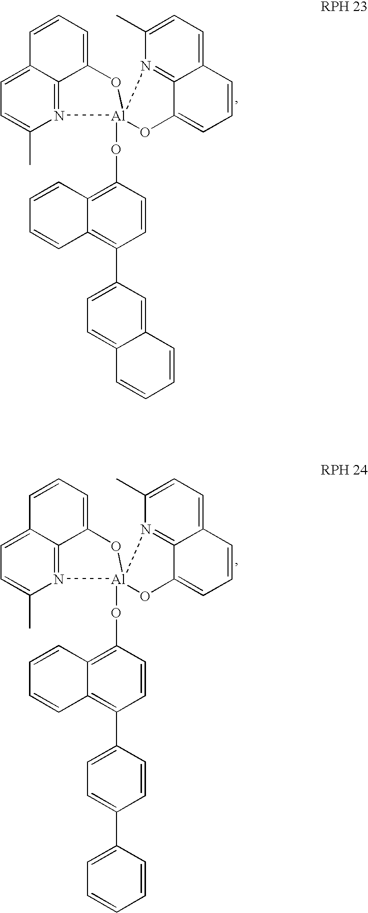

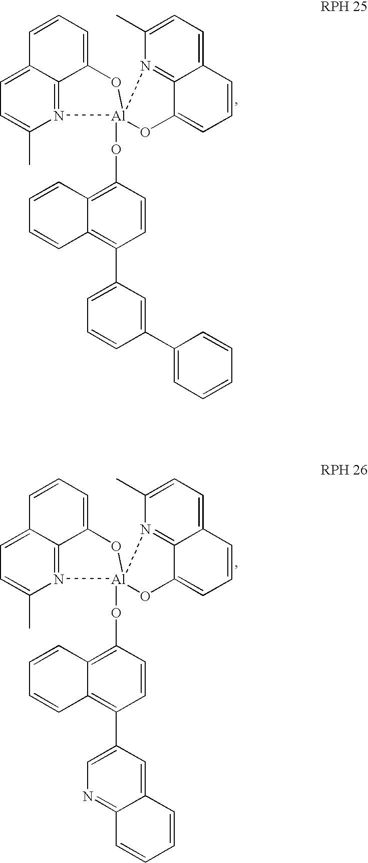

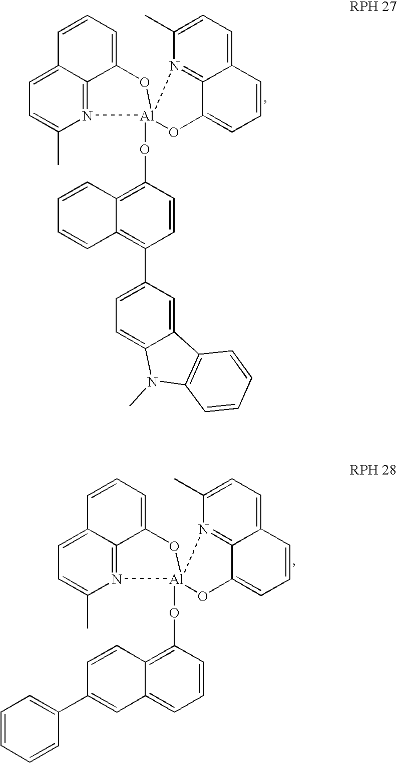

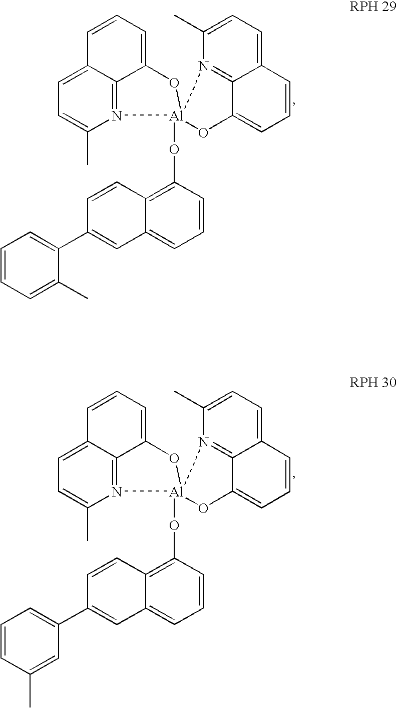

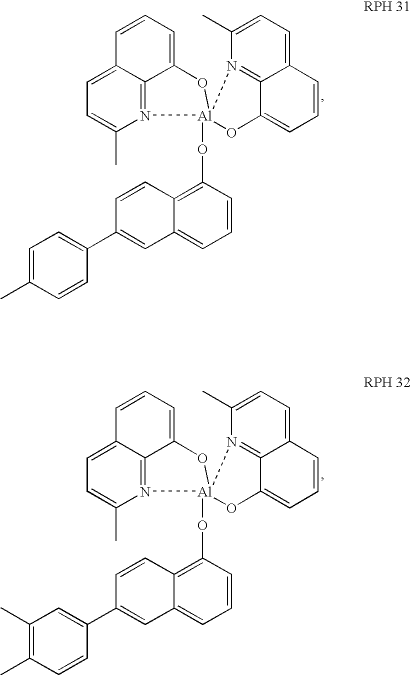

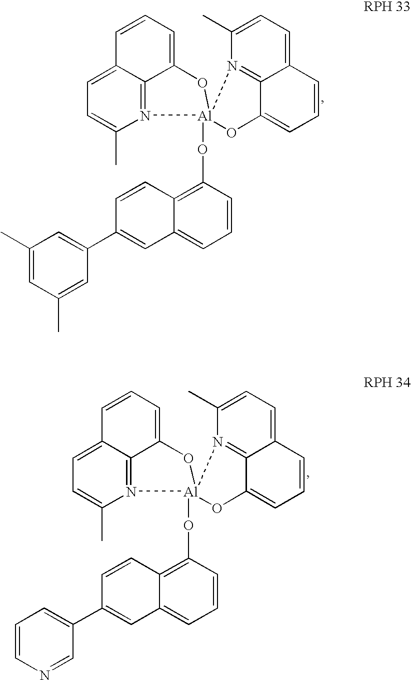

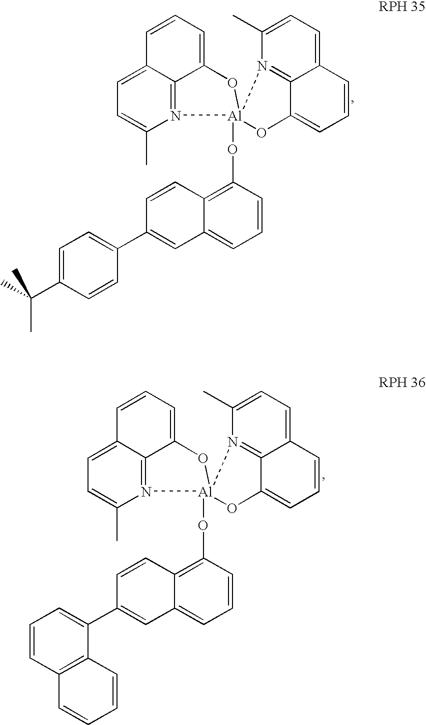

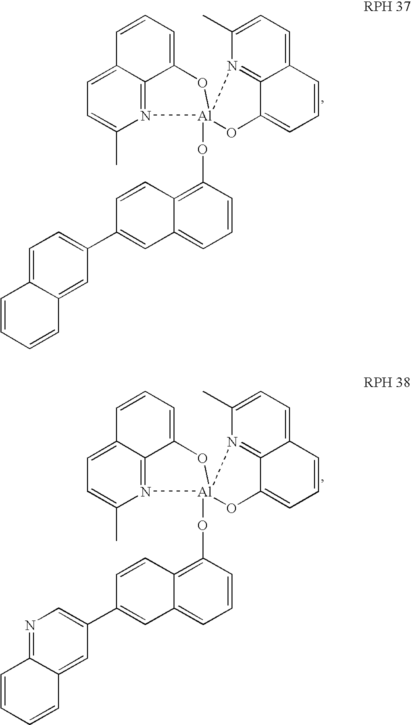

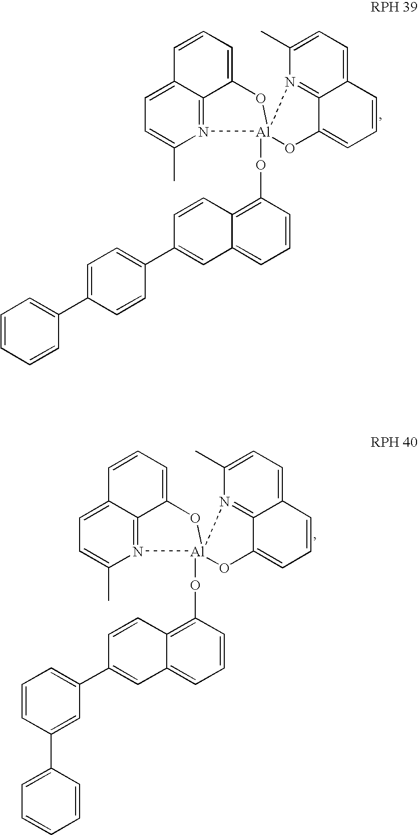

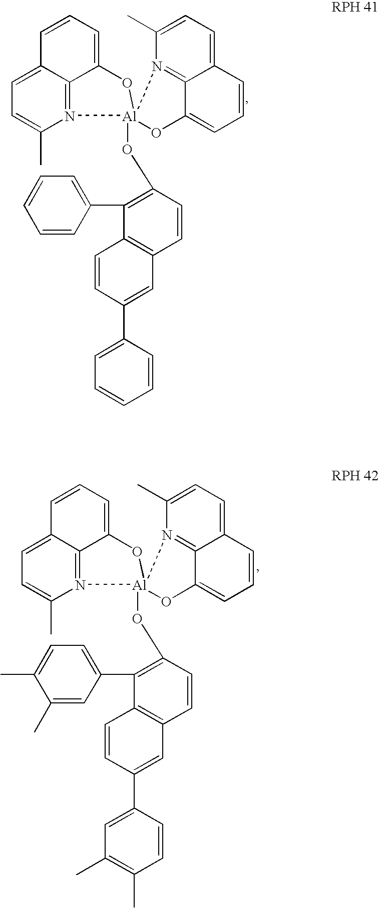

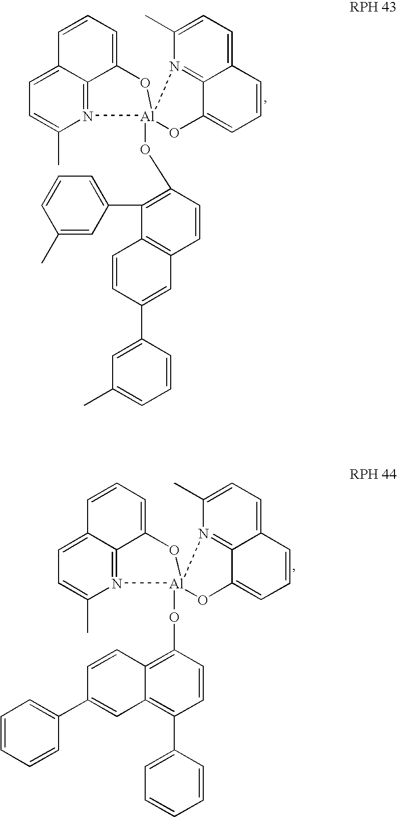

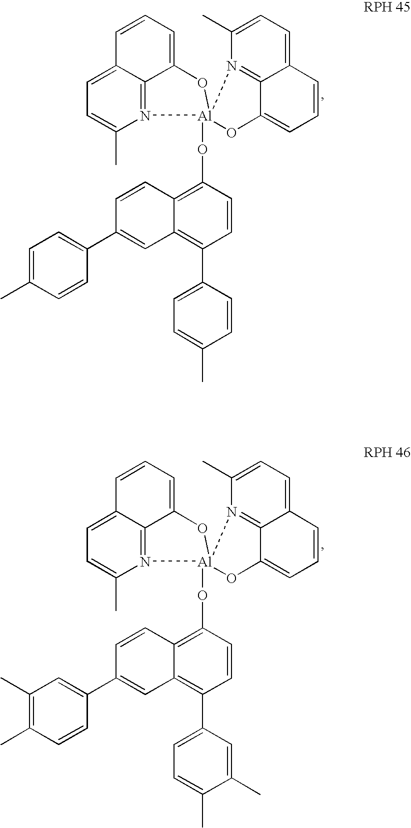

In a preferred embodiment of the present invention, the organometallic complex may be selected from the group consisting of the following compounds:

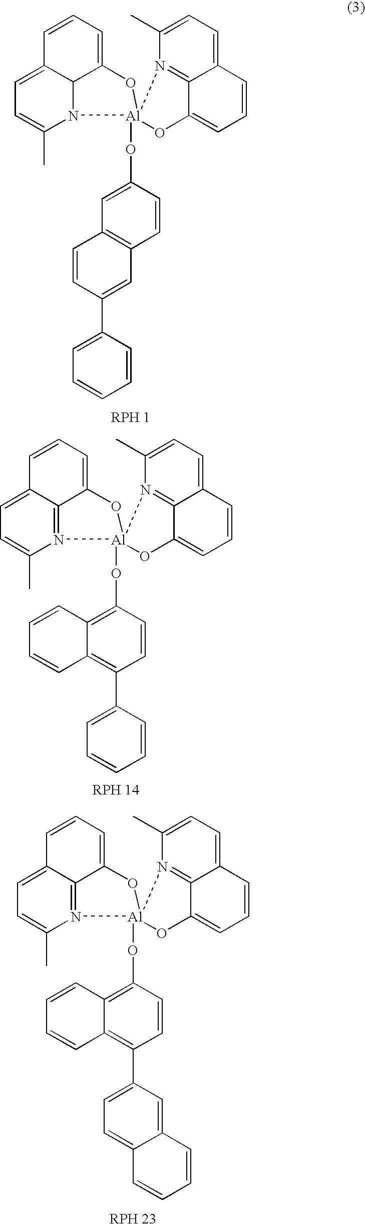

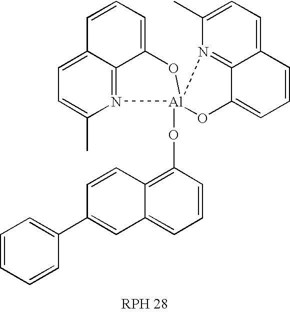

In accordance with another aspect of the present invention for achieving the second object, there is provided an organic light-emitting diode comprising an anode, an organic light-emitting layer and a cathode wherein the organic light-emitting layer includes the organometallic complex represented by Formula 1.

In an embodiment of the present invention, the organic light-emitting diode may comprise an iridium complex as a dopant of the organic light-emitting layer.

The iridium complex may be

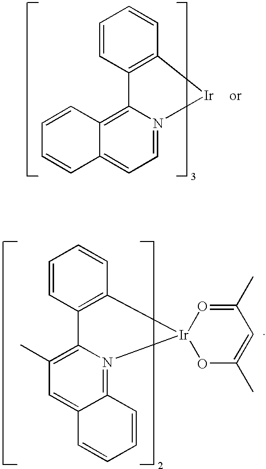

In a further embodiment of the present invention, the dopant is preferably used in an amount of 0.1 to 30% by weight of the organometallic complex.

The organic light-emitting diode of the present invention may further comprise a hole transport layer disposed between the anode and the organic light-emitting layer, and an electron transport layer disposed between the cathode and the organic light-emitting layer.

The organic light-emitting diode of the present invention may further comprise a hole injecting layer disposed under the hole transport layer.

The organic light-emitting diode of the present invention may further comprise an electron injecting layer disposed on the electron transport layer.

In another embodiment of the present invention, the hole transport layer may be formed of N,N′-bis(3-methylphenyl)-N,N′-diphenyl-[1,1′-biphenyl]-4,4′-diamine (TPD) or N,N′-di(naphthalen-1-yl)-N,N′-diphenyl-benzidine (α-NPD).

In a preferred embodiment of the present invention, the hole injecting layer may be formed of copper phthalocyanine (CuPc), 4,4′,4″-tri(N-carbazolyl)triphenylamine (TCTA) or 4,4′,4″-tris(3-methylphenylphenylamino)triphenylamine (m-MTDATA).

### BRIEF DESCRIPTION OF THE DRAWINGS

The above and other objects, features and other advantages of the present invention will be more clearly understood from the following detailed description taken in conjunction with the accompanying drawing, in which:

FIG. 1 is a schematic cross-sectional view of an organic light-emitting diode according to an embodiment of the present invention.

### DETAILED DESCRIPTION OF THE PREFERRED EMBODIMENTS

The present invention will now be described in more detail.

The organometallic complex for an organic light-emitting layer according to the present invention is characterized in that it is prepared by modifying a known BAlq derivative to improve the bulk packing characteristics, thus achieving a considerable improvement in the efficiency and lifetime of an organic light-emitting diode using the organometallic complex.

An organic light-emitting layer formed using the organometallic complex employs a host-dopant system based on an energy transfer principle wherein a host is doped with a dopant. In order to effectively use the dopant for light emission and the host for charge transport in the host-dopant system, the following characteristics must be in harmony as a whole: high photoluminescence (PL) efficiency, chemical stability against deposition without degradation, optimal energy levels for balanced charge injection and transport, stability on a molecular level, possible formation of a structurally stable film, etc. These characteristics are determined by the optical and electrical properties of the molecules as well as the bulk packing of the molecules formed by vapor deposition. In conclusion, the optical and electrical properties of the host and the dopant of the organic light-emitting layer and the bulk packing of the molecules formed by vapor deposition may be important factors in determining the lifetime and efficiency of a device comprising the organic light-emitting layer.

The electron density of the highest-occupied molecular orbital (HOMO) of BAlq is concentrated in the phenolic rings of the isoquinoline ligands, whereas that of the lowest-unoccupied molecular orbital (LUMO) of BAlq is concentrated in the pyridyl rings of the isoquinoline ligands. The introduction of a substituent to the isoquinoline ligand leads to a change in the electronic structure or affects the overlap between the phenolic rings and the pyridyl rings, resulting in an increased danger of adverse effects, such as decreased charge carrier mobility. In addition, the possibility that the aluminum may react with oxygen and other materials cannot be excluded. To avoid such problems, the use of an appropriate ligand capable of protecting the aluminum from external attack through steric hindrance is considered. Examples of such ligands include ligands of various structures, such as anthracene, pyrene and perylene. Although it is estimated that the use of a larger ligand facilitates the protection of the aluminum, the use of too large a ligand may make the formation of a bond with the aluminum impossible due to steric hindrance or may increase the possibility of affecting the bonding of the isoquinoline ligands. In view of the foregoing problems, a naphthalene group, which is found to have an appropriate size, is introduced to the organometallic complex of the present invention instead of biphenyl without deforming the substituents of the isoquinoline ligands. As a result, an increase in the lifetime of the organometallic complex can be expected due to the protective effects on the aluminum. Substitution with a simple naphthalene ring may cause the danger that intermolecular π-π stacking will not be facilitated due to steric effects. In the present invention, an aromatic ring is additionally introduced to a naphthalene ring so as to facilitate π-π stacking, and as a result, the bulk packing characteristics of the molecules are improved, thereby achieving an increase in the efficiency of an organic light-emitting device comprising the organometallic complex of the present invention.

The organic light-emitting diode of the present invention comprises an organic light-emitting layer including the organometallic complex of Formula 1, an anode and a cathode. The organic light-emitting diode of the present invention is characterized by high efficiency and long lifetime, which are attributed to the structural characteristics of the organometallic complex.

As mentioned earlier, the organic light-emitting layer used in the present invention employs a host-dopant system. A host material and a dopant material only can generally be used to emit light. In this case, however, the efficiency and luminance of a light-emitting layer formed using the materials are very low. In addition, the individual molecules are in close proximity to each other to cause the formation of eximers, and as a result, the inherent characteristics of the individual molecules are not sufficiently observed. Accordingly, it is preferred to dope the host material with the dopant material to form a light-emitting layer.

The dopant is not particularly limited so long as it is routinely used in the art. As the dopant, there may be exemplified an iridium complex.

Particularly, the dopant may be 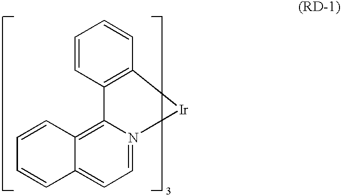
or

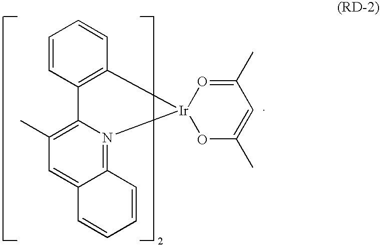

It is preferred that the dopant be used in an amount of 0.1 to 30% by weight of the organometallic complex. When the dopant is used in an amount smaller than 0.1% by weight, the addition effects of the dopant are no or few. Meanwhile, when the dopant is used in an amount larger than 30% by weight, there arises the risk that the efficiency of the device may be decreased due to triplet-triplet annihilation.

The organic light-emitting diode of the present invention may further comprise a hole transport layer (HTL) disposed between the anode and the organic light-emitting layer, and an electron transport layer (ETL) disposed between the cathode and the organic light-emitting layer. The hole transport layer is formed to facilitate the injection of holes from the anode. As an exemplary material for the hole transport layer, an electron-donating compound having a low ionization potential is used. Examples of widely used electron-donating compounds include diamine, triamine and tetraamine derivatives whose basic skeleton is triphenylamine. Any material that is commonly used in the art may be used to form the hole transport layer in the present invention, and examples thereof include, but are not limited to, N,N′-bis(3-methylphenyl)-N,N′-diphenyl-[1,1′-biphenyl]-4,4′-diamine (TPD) and N,N′-di(naphthalen-1-yl)-N,N′-diphenyl-benzidien (α-NPD).

The organic light-emitting diode of the present invention may further comprise a hole injecting layer (HIL) disposed under the hole transport layer. Any material that is commonly used in the art may be used without any particular limitation to form the hole injecting layer in the present invention. Suitable materials for the hole injecting layer include CuPc and starburst-type amines, e.g., TCTA, m-MTDATA and IDE406 (available from Idemitsu), some of which are enumerated below:

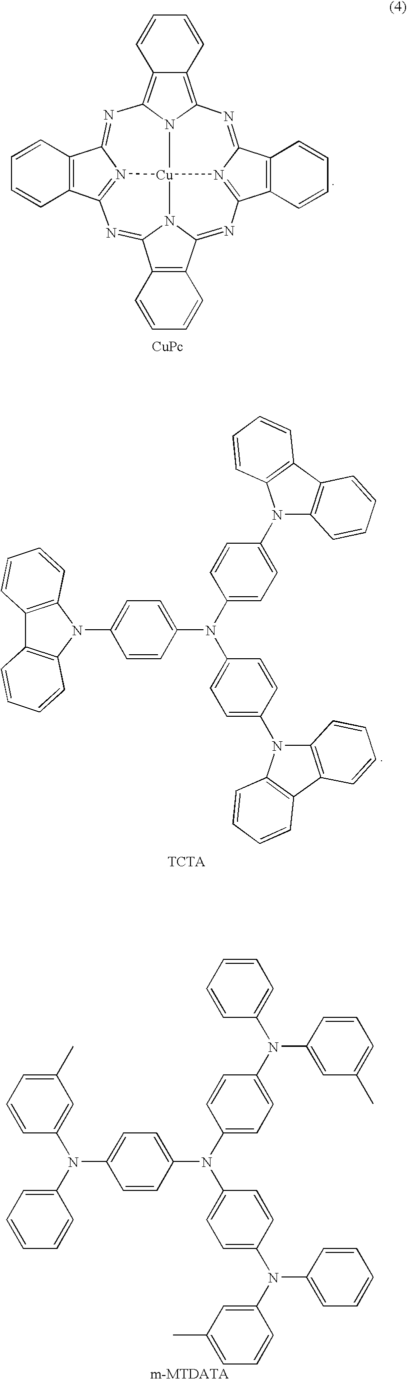

The electron transport layer of the organic light-emitting diode according to the present invention serves to sufficiently transport electrons from the cathode to the organic light-emitting layer, and to inhibit the migration of unbound holes in the organic light-emitting layer, thereby increasing the opportunity for the unbound holes to recombine with the electrons in the emitting layer. It is to be understood that any material can be used without any particular limitation to form the electron transport layer so long as it is commonly used in the art. For example, an oxadiazole derivative, such as PBD, BMD, BND or Alq₃, may be used to form the electron transport layer. The organic light-emitting diode of the present invention may further comprise an electron injecting layer (EIL) disposed on the electron transport layer to facilitate the injection of electrons from the cathode. The formation of the electron injecting layer contributes to an improvement in the power efficiency of the device. Any material that is commonly used in the art may be used to form the electron injecting layer in the present invention, and examples thereof include, but are not limited to, LiF, NaCl, CsF, Li₂O and BaO.

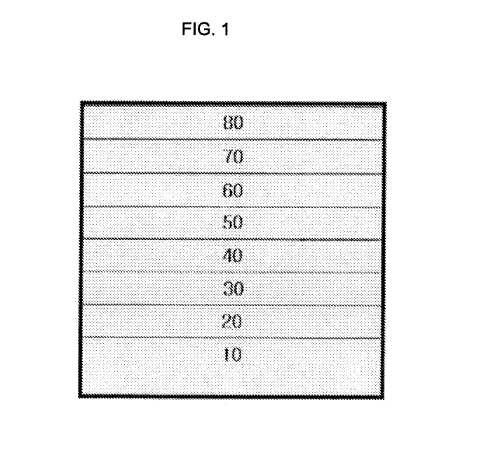

FIG. 1 is a cross-sectional view showing the structure of an organic electroluminescent device according to an embodiment of the present invention. The organic light-emitting diode of the present invention comprises an anode 20, a hole transport layer 40, an organic light-emitting layer 50, an electron transport layer 60, and a cathode 80. If necessary, the organic light-emitting diode may further comprise a hole injecting layer 30 and an electron injecting layer 70. In addition to the hole and electron injecting layers, the organic light-emitting diode may further comprise one or two intermediate layers, and optionally together with a hole blocking layer or an electron blocking layer.

With reference to FIG. 1, the organic electroluminescent device of the present invention and a fabrication method thereof will be explained below. First, an anode material is coated on a substrate 10 to form an anode 20. The substrate 10 may be any one used in common organic EL devices. An organic substrate or a transparent plastic substrate is preferred in terms of transparency, surface smoothness, ease of handling and waterproof qualities. As the anode material, a transparent and electrically conductive material is used, for example, indium tin oxide (ITO), indium zinc oxide (IZO), tin oxide (SnO₂) or zinc oxide (ZnO). A hole injecting material is deposited on the anode 20 by vacuum thermal evaporation or spin coating to form a hole injecting layer 30, and then a hole transport material is deposited on the hole injecting layer 30 by vacuum thermal evaporation or spin coating to form a hole transport layer 40. Subsequently, an organic light-emitting layer 50 is formed on the hole transport layer 40. If desired, a hole blocking layer (not shown) may be formed on the organic light-emitting layer 50 by vacuum deposition or spin coating. The hole blocking layer is formed of a material having a very low HOMO level to eliminate the problems, i.e. shortened lifetime and low efficiency of the device, which are encountered when holes enter the cathode through the organic light-emitting layer. The hole blocking material is not particularly restricted, but it must have the ability to transport electrons and a higher ionization potential than the light-emitting compound. Representative hole blocking materials are BAlq, BCP and TPBI. An electron transport layer 60 is formed on the hole blocking layer by vacuum deposition or spin coating, an electron injecting layer 70 is formed thereon. A cathode metal is deposited on the electron injecting layer 70 by vacuum thermal evaporation to form a cathode 80, completing the fabrication of the organic electroluminescent (EL) device.

As the cathode metal, there may be used, for example, lithium (Li), magnesium (Mg), aluminum (Al), aluminum-lithium (Al—Li), calcium (Ca), magnesium-indium (Mg—In), magnesium-silver (Mg—Ag), or the like. A light-transmissive cathode made of ITO or IZO may be used to fabricate a top emission device.

Hereinafter, the present invention will be explained in more detail with reference to the following preferred examples. However, these examples are not intended to limit the present invention.

### EXAMPLES

### Example 1

### 1-(1): Synthesis of 2-bromo-6-ethoxynaphthalene

6-Bromo-2-naphthol (25 g), water (250 ml) and 1,4-dioxane (250 ml) were stirred in a three-neck round-bottom flask (1,000 ml) at room temperature. To the mixture was added a solution of sodium hydroxide in water (100 ml). After the crystals were completely dissolved, a dilute solution of diethyl sulfate (17.3 g) in 1,4-dioxane (100 ml) was slowly added thereto at room temperature. After the addition was finished, the resulting mixture was refluxed for 12 hours to obtain a white crystal. After completion of the reaction, ethyl acetate (EA) was added to the reaction mixture for phase separation. The obtained organic layer was collected, washed once with water, and concentrated under a reduced pressure to remove the solvent and obtain a crystal. The crystal was mixed with a small amount of methanol, stirred for 10 minutes, and filtered to yield 9 g of 2-bromo-6-ethoxynaphthalene.

### 1-(2): Synthesis of 2-phenyl-6-ethoxynaphthalene

2-Bromo-6-ethoxynaphthalene (6 g), phenylboronic acid (3.2 g), potassium carbonate (10.9 g), water (60 ml) and toluene (180 ml) were stirred in a 500 ml round-bottom flask. To the mixture was added 0.6 g of tetrakis(triphenylphosphine)palladium (0) under a nitrogen atmosphere. The resulting mixture was allowed to react with stirring for 6 hours while the temperature was raised to 90° C. After completion of the reaction, toluene was added to the reaction mixture for phase separation. The toluene layer was collected, concentrated under a reduced pressure to remove the solvent, and purified by column chromatography using methylene chloride (MC). The MC extract was concentrated, mixed with a small amount of methanol, and filtered to yield 4.5 g of 2-phenyl-6-ethoxynaphthalene.

### 1-(3): Synthesis of 6-phenyl-2-naphthol

2-Phenyl-6-ethoxynaphthalene (4.5 g), 48% hydrobromic acid (90 ml) and acetic acid (200 ml) were placed in a 500-ml round-bottom flask. The mixture was refluxed for 24 hours while the temperature was raised to 110° C. After completion of the reaction, the reaction mixture was cooled to room temperature and poured into 1,000 ml of water to obtain a white crystal. The crystal was filtered, dissolved in MC, washed three times with water, concentrated under a reduced pressure, and purified by column chromatography using MC. The MC extract was recrystallized from hexane to yield 3.3 g of 6-phenyl-2-naphthol.

### 1-(4): Synthesis of RPH-1

8-Hydroxy-2-methylquinoline (2.4 g), aluminum propoxide (3.1 g) and anhydrous ethanol (110 ml) were placed in a 250 ml round-bottom flask, and then the mixture was allowed to react with stirring at room temperature for 4 hours. After completion of the reaction, undissolved materials of the reaction mixture were filtered through celite. The filtrate was transferred to a 250 ml round-bottom flask, and 8-hydroxy-2-methylquinoline (2.4 g) and 6-phenyl-2-naphthol (3.3 g) were added thereto. The resulting mixture was refluxed for 24 hours while the temperature was raised to 80° C. After completion of the reaction, the reaction mixture was allowed to cool to room temperature and filtered to obtain a crystal. The crystal washed using anhydrous ethanol to yield 2.8 g of RPH1. Elemental analysis of RPH1 was carried out using an elemental analyzer (EA-1100). The results of the elemental analysis and the theoretical values of RPH1 are shown in Table 1. The results show that the measured values agree well with the theoretical values, indicating that the desired organometallic complex for an organic light-emitting layer was successfully synthesized.

TABLE 1

| | N | C | H |
|---|---|---|---|
| Theoretical value (%) | 4.98 | 76.8 | 4.84 |
| Measured value (%) | 4.96 | 77.6 | 4.97 |

### 1-(5): Fabrication of Organic Light-Emitting Diode

An ITO-deposited glass substrate was patterned to have a light-emitting area of 3 mm×3 mm, followed by cleaning. After the substrate was mounted in a vacuum chamber, the pressure of the chamber was adjusted to 1×10⁻⁶ torr. CuPC (200 Å), NPD (400 Å), RPH-1 synthesized in Example 1-(4)+RD-1 (7%) (200 Å), Alq₃ (300 Å), LiF (5 Å) and Al (1,000 Å) were deposited in this order on the ITO to form respective films, completing the fabrication of an organic light-emitting diode.

### Example 2

### 2-(1): Synthesis of 1-methoxy-4-bromonaphthalene

1-Methoxynaphthalene (3.5 g) and acetonitrile (350 ml) were stirred in a 500 ml round-bottom flask. To the mixture was added N-bromosuccinic acid (3.5 g) in three divided portions. The resulting mixture was allowed to react at room temperature for 10 hours. After completion of the reaction, the reaction mixture was concentrated under a reduced pressure to remove the solvent and purified by column chromatography using hexane. The hexane was concentrated to yield 4.4 g of the title compound as a gel-liquid phase.

### 2-(2): Synthesis of 1-methoxy-4-phenylnaphthalene

1-Methoxy-4-bromonaphthalene (4.4 g), phenylboronic acid (3.4 g), potassium carbonate (7.7 g), water (50 ml), toluene (200 ml) and tetrahydrofuran (100 ml) were stirred in a 500 ml round-bottom flask. To the mixture was added 0.2 g of tetrakis(triphenylphosphine)palladium (0) under a nitrogen atmosphere. The resulting mixture was stirred for 24 hours while the temperature was raised to 90° C. After completion of the reaction, toluene was added to the reaction mixture for phase separation. The toluene layer was collected, concentrated under a reduced pressure to remove the solvent, and purified by column chromatography using MC. The MC extract was concentrated, mixed with a small amount of methanol, and filtered to yield 5.1 g of 1-methoxy-4-phenylnaphthalene.

### 2-(3): Synthesis of 4-phenylnaphthol

1-Methoxy-4-phenylnaphthalene (5.1 g), 48% hydrobromic acid (100 ml) and acetic acid (250 ml) were placed in a 500 ml round-bottom flask. The mixture was refluxed for 24 hours while the temperature was raised to 110° C. After completion of the reaction, the reaction mixture was cooled to room temperature and poured into 1,000 ml of water to obtain a white crystal. The crystal was filtered, dissolved in MC, washed three times with water, concentrated under a reduced pressure, and purified by column chromatography using MC. The MC extract was recrystallized from hexane to yield 4.8 g of 4-phenylnaphthol.

### 2-(4): Synthesis of RPH14

8-Hydroxy-2-methylquinoline (3.2 g), aluminum isopropoxide (3.7 g) and anhydrous ethanol (150 ml) were placed in a 500 ml round-bottom flask, and then the mixture was allowed to react with stirring at room temperature for 4 hours. After completion of the reaction, undissolved materials of the reaction mixture were filtered through celite. The filtrate was transferred to a 500 ml round-bottom flask, and 8-hydroxy-2-methylquinoline (2.4 g) and 4-phenylnaphthol (3.7 g) were added thereto. The resulting mixture was refluxed for 24 hours while the temperature was raised to 80° C. After completion of the reaction, the reaction mixture was allowed to cool to room temperature and filtered to obtain a crystal. The crystal washed using anhydrous ethanol to yield 10.2 g of RPH14. Elemental analysis of RPH14 was carried out using an elemental analyzer (EA-1100). The results of the elemental analysis and the theoretical values of RPH14 are shown in Table 2. The results show that the measured values agree well with the theoretical values, indicating that the desired organometallic complex for an organic light-emitting layer was successfully synthesized.

TABLE 2

| | N | C | H |
|---|---|---|---|
| Theoretical value (%) | 4.98 | 76.8 | 4.84 |
| Measured value (%) | 4.99 | 77.6 | 4.99 |

### 2-(5): Fabrication of Organic Light-Emitting Diode

An ITO-deposited glass substrate was patterned to have a light-emitting area of 3 mm×3 mm, followed by cleaning. After the substrate was mounted in a vacuum chamber, the pressure of the chamber was adjusted to 1×10⁻⁶ torr. CuPC (200 Å), NPD (400 Å), RPH-14 synthesized in Example 2-(4)+RD-1 (7%) (200 Å), Alq₃ (300 Å), LiF (5 Å) and Al (1,000 Å) were deposited in this order on the ITO to form respective films, completing the fabrication of an organic light-emitting diode.

### Example 3

### 3-(1): Synthesis of 1-methoxy-4-(2-naphthyl)-naphthalene

1-Methoxy-4-bromo-naphthalene (10 g), 2-naphthaleneboronic acid (8.7 g), potassium carbonate (17.5 g), water (100 ml) and toluene (300 ml) were stirred in a 500 ml round-bottom flask. To the mixture was added 1 g of tetrakis(triphenylphosphine)palladium (0) under a nitrogen atmosphere. The resulting mixture was allowed to react with stirring for 24 hours while the temperature was raised to 90° C. After completion of the reaction, toluene was added to the reaction mixture for phase separation. The toluene layer was collected, concentrated under a reduced pressure to remove the solvent, and purified by column chromatography using MC. The MC extract was concentrated, mixed with a small amount of methanol, and filtered to yield of 10.1 g of 1-methoxy-4-(2-naphthyl)-naphthalene.

### 3-(2): Synthesis of 4-(2-naphthyl)-naphthol

1-Methoxy-4-(2-naphthyl)-naphthalene (10.1 g), 48% hydrobromic acid (200 ml) and acetic acid (500 ml) were placed in a 500-ml round-bottom flask. The mixture was refluxed for 24 hours while the temperature was raised to 110° C. After completion of the reaction, the reaction mixture was cooled to room temperature and poured into 1,000 ml of water to obtain a white crystal. The crystal was filtered, dissolved in MC, washed three times with water, concentrated under a reduced pressure, and purified by column chromatography using MC. The MC extract was recrystallized from hexane to yield 8.2 g of 4-(2-naphthyl)-naphthol.

### 3-(3): Synthesis of RPH23

8-Hydroxy-2-methylquinoline (4.8 g), aluminum isopropoxide (6.2 g) and anhydrous ethanol (250 ml) were placed in a 500 ml round-bottom flask, and then the mixture was allowed to react with stirring at room temperature for 4 hours. After completion of the reaction, undissolved materials of the reaction mixture were filtered through celite. The filtrate was transferred to a 500 ml round-bottom flask, and 8-hydroxy-2-methylquinoline (4.8 g) and 4-(2-naphthyl)-naphthol (8.2 g) were added thereto. The resulting mixture was refluxed for 24 hours while the temperature was raised to 80° C. After completion of the reaction, the reaction mixture was allowed to cool to room temperature and filtered to obtain a crystal. The crystal washed using anhydrous ethanol to yield 15 g of RPH23. Elemental analysis of RPH23 was carried out using an elemental analyzer (EA-1100). The results of the elemental analysis and the theoretical values of RPH24 are shown in Table 3. The results show that the measured values agree well with the theoretical values, indicating that the desired organometallic complex for an organic light-emitting layer was successfully synthesized.

TABLE 3

| | N | C | H |
|---|---|---|---|
| Theoretical value (%) | 4.57 | 78.4 | 4.78 |
| Measured value (%) | 4.59 | 79.27 | 4.91 |

### 3-(4): Fabrication of Organic Light-Emitting Diode

An ITO-deposited glass substrate was patterned to have a light-emitting area of 3 mm×3 mm, followed by cleaning. After the substrate was mounted in a vacuum chamber, the pressure of the chamber was adjusted to 1×10⁻⁶ torr. CuPC (200 Å), NPD (400 Å), RPH-23 synthesized in Example 3-(3)+RD-1 (7%) (200 Å), Alq₃ (300 Å), LiF (5 Å) and Al (1,000 Å) were deposited in this order on the ITO to form respective films, completing the fabrication of an organic light-emitting diode.

### Example 4

### 4-(1): Synthesis of 1,6-dibromo-2-ethoxynaphthalene

1,6-Dibromo-2-naphthol (25 g) and water (250 ml) were stirred in a 500 ml round-bottom flask. To the mixture was slowly added a solution of sodium hydroxide (4.3 g) in water (100 ml). After stirring was continued until the crystals were completely dissolved, diethyl sulfate (17.3 g) was slowly added thereto. The resulting mixture was refluxed for 12 hours. After completion of the reaction, ethyl acetate (EA) was added to the reaction mixture for phase separation. The obtained organic layer was collected, washed once with water, and concentrated under a reduced pressure to remove the solvent and obtain a crystal. The crystal was mixed with a small amount of methanol, stirred for 10 minutes, and filtered to yield 20 g of 1,6-dibromo-2-ethoxynaphthalene.

### 4-(2): Synthesis of 1,6-diphenyl-2-ethoxynaphthalene

1,6-Dibromo-2-ethoxynaphthalene (9 g), phenylboronic acid (7.3 g), potassium carbonate (25 g), water (90 ml) and toluene (250 ml) were stirred in a 500 ml round-bottom flask. To the mixture was added 0.6 g of tetrakis(triphenylphosphine)palladium (0) under a nitrogen atmosphere. The resulting mixture was allowed to react with stirring for 6 hours while the temperature was raised to 90° C. After completion of the reaction, toluene was added to the reaction mixture for phase separation. The toluene layer was collected, concentrated under a reduced pressure to remove the solvent, and purified by column chromatography using MC. The MC extract was concentrated, mixed with a small amount of methanol, and filtered to yield 8.1 g of 1,6-diphenyl-2-ethoxynaphthalene.

### 4-(3): Synthesis of 1,6-diphenyl-2-naphthol

1,6-Diphenyl-2-ethoxynaphthalene (8.1 g), 48% hydrobromic acid (80 ml) and acetic acid (400 ml) were placed in a 500-ml round-bottom flask. The mixture was refluxed for 24 hours while the temperature was raised to 110° C. After completion of the reaction, the reaction mixture was cooled to room temperature and poured into 1,000 ml of water to obtain a white crystal. The crystal was filtered, dissolved in MC, washed three times with water, concentrated under a reduced pressure, and purified by column chromatography using MC. The MC extract was recrystallized from hexane to yield 7 g of 1,6-diphenyl-2-naphthol.

### 4-(4): Synthesis of RPH41

8-Hydroxy-2-methylquinoline (2.1 g), aluminum isopropoxide (2.8 g) and anhydrous ethanol (100 ml) were placed in a 250 ml round-bottom flask, and then the mixture was allowed to react with stirring at room temperature for 4 hours. After completion of the reaction, undissolved materials of the reaction mixture were filtered through celite.

The filtrate was transferred to a 250 ml round-bottom flask, and 8-hydroxy-2-methylquinoline (2.1 g) and 1,6-diphenyl-2-naphthol (4 g) were added thereto. The resulting mixture was refluxed for 24 hours while the temperature was raised to 80° C. After completion of the reaction, the reaction mixture was allowed to cool to room temperature and filtered to obtain a crystal. The crystal washed using anhydrous ethanol to yield 5 g of RPH41. Elemental analysis of RPH41 was carried out using an elemental analyzer (EA-1100). The results of the elemental analysis and the theoretical values of RPH41 are shown in Table 4. The results show that the measured values agree well with the theoretical values, indicating that the desired organometallic complex for an organic light-emitting layer was successfully synthesized.

TABLE 4

| | N | C | H |
|---|---|---|---|
| Theoretical value (%) | 4.38 | 78.9 | 4.90 |
| Measured value (%) | 4.39 | 79.7 | 5.06 |

### 4-(5): Fabrication of Organic Light-Emitting Diode

An ITO-deposited glass substrate was patterned to have a light-emitting area of 3 mm×3 mm, followed by cleaning. After the substrate was mounted in a vacuum chamber, the pressure of the chamber was adjusted to 1×10⁻⁶ torr. CuPC (200 Å), NPD (400 Å), RPH-41 synthesized in Example 4-(4)+RD-1 (7%) (200 Å), Alm (300 Å), LiF (5 Å) and Al (1,000 Å) were deposited in this order on the ITO to form respective films, completing the fabrication of an organic light-emitting diode.

### Comparative Example 1

An ITO-deposited glass substrate was patterned to have a light-emitting area of 3 mm×3 mm, followed by cleaning. After the substrate was mounted in a vacuum chamber, the pressure of the chamber was adjusted to 1×10⁻⁶ torr. CuPC (200 Å), NPD (400 Å), BAlq+RD-1 (7%) (200 Å), Alq₃ (300 Å), LiF (5 Å) and Al (1,000 Å) were deposited in this order on the ITO to form respective films, completing the fabrication of an organic light-emitting diode.

### Comparative Example 2

An ITO-deposited glass substrate was patterned to have a light-emitting area of 3 mm×3 mm, followed by cleaning. After the substrate was mounted in a vacuum chamber, the pressure of the chamber was adjusted to 1×10⁻⁶ torr. CuPC (200 Å), NPD (400 Å), the compound of Formula 5+RD-1 (7%) (200 Å), Alq₃ (300 Å), LiF (5 Å) and Al (1,000 Å) were deposited in this order on the ITO to form respective films, completing the fabrication of an organic light-emitting diode.

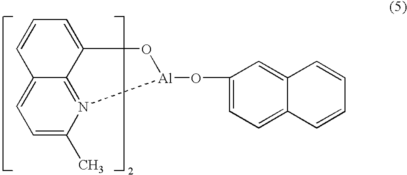

### Test Example 1

The efficiency of the organic light-emitting diodes fabricated in Examples 1 to 4 and Comparative Examples 1 and 2 was measured at a current density of 0.9 mA/cm². The chromaticity coordinates of the devices were measured. The half-life of luminescence with respect to the initial luminance of the devices was measured when the devices were driven at a constant DC current. The results are shown in Table 5.

TABLE 5

| | | | | Current | Power | | | |
|---|---|---|---|---|---|---|---|---|
| Example | Voltage | Current | Luminance | efficiency | efficiency | CIE | CIE | Lifetime |
| No. | (V) | (mA) | (cd/m²⁾ | (cd/A) | (1 m/W) | (X) | (Y) | (h)* |
| Example 1 | 6.0 | 0.9 | 1198 | 12.0 | 6.26 | 0.641 | 0.337 | 5000 |
| Example 2 | 6.3 | 0.9 | 1220 | 12.2 | 6.08 | 0.635 | 0.336 | 6000 |
| Example 3 | 6.0 | 0.9 | 1215 | 12.2 | 6.35 | 0.636 | 0.337 | 5000 |
| Example 4 | 6.1 | 0.9 | 1208 | 12.1 | 6.21 | 0.640 | 0.338 | 4000 |
| Comparative | 7.5 | 0.9 | 1170 | 11.7 | 5.48 | 0.636 | 0.338 | 2500 |
| Example 1 | | | | | | | | |
| Comparative | 6.7 | 0.9 | 1094 | 10.9 | 5.13 | 0.627 | 0.356 | 3000 |
| Example 2 | | | | | | | | |

As can be seen from the results of Table 5, the lifetime values of the organic light-emitting diodes fabricated in Examples 1 to 4 were from 1.3 times to 2.4 times longer than those of the organic light-emitting diodes fabricated in Comparative Examples 1 and 2. In addition, the current efficiency and the power efficiency of the organic light-emitting diodes fabricated in Examples 1 to 4 were higher than those of the organic light-emitting diodes fabricated in Comparative Examples 1 and 2.

As apparent from the above description, a naphthalene derivative as a ligand is introduced to the organometallic complex of the present invention. The organic light-emitting diode of the present invention uses the organometallic complex as a phosphorescent host material. The organic light-emitting diode of the present invention exhibits high current efficiency, high power efficiency and long lifetime when compared to conventional devices using BAlq.

1. An organometallic complex for an organic light-emitting layer, represented by Formula 1: 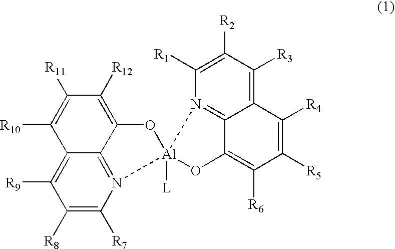
wherein R₁ to R₁₂ are each independently hydrogen, amino, C₁-C₁₀ alkyl, C₁-C₁₀ alkenyl, C₁-C₁₀ alkynyl, or C₁-C₁₀ alkoxy, and
L is 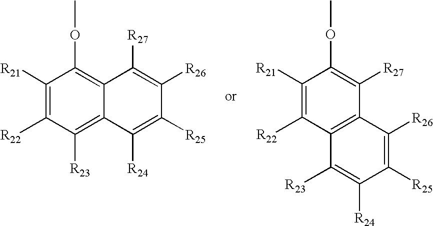
(wherein R₂₁ to R₂₇ are each independently hydrogen, amino, a C₆-C₂₀ aryl group which is unsubstituted or substituted with a group selected from the group consisting of C₁-C₁₀ alkyl, C₁-C₁₀ alkoxy, cyano, C₁-C₁₀ alkylamino, C₁-C₁₀ alkylsilyl, halogen, C₆-C₁₀ aryl, C₆-C₁₀ aryloxy, C₆-C₁₀ arylamino and C₆-C₁₀ arylsilyl, or a C₄-C₁₉ heteroaryl group containing at least one heteroatom selected from N, S and O atoms, with the proviso that at least one group of R₂₁ to R₂₇ is a C₆-C₂₀ aryl group which is unsubstituted or substituted with a group selected from the group consisting of C₁-C₁₀ alkyl, C₁-C₁₀ alkoxy, cyano, C₁-C₁₀ alkylamino, C₁-C₁₀ alkylsilyl, halogen, C₆-C₁₀ aryl, C₆-C₁₀ aryloxy, C₆-C₁₀ arylamino and C₆-C₁₀ arylsilyl, or a C₄-C₁₉ heteroaryl group containing at least one heteroatom selected from N, S and O atoms).

2. The organometallic complex according to claim 1, wherein the organometallic complex is selected from the following compounds:

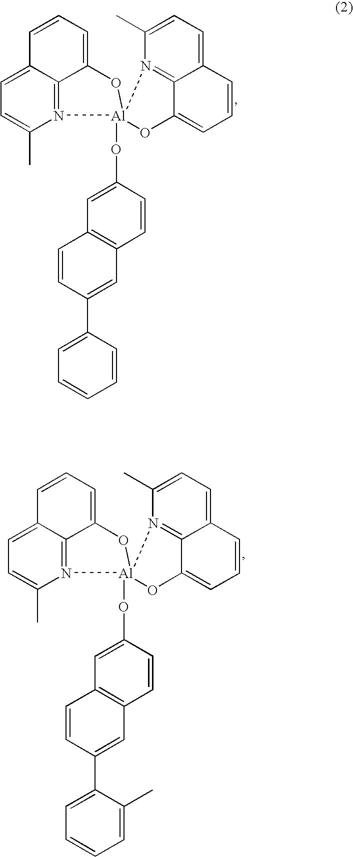

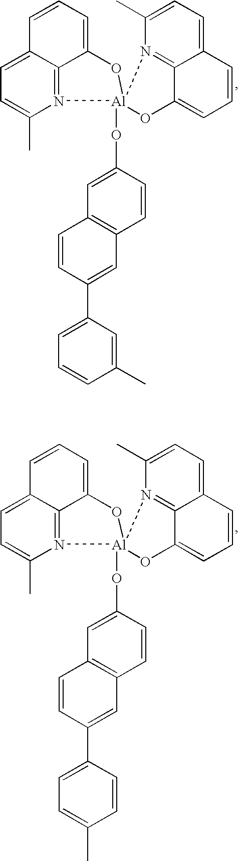

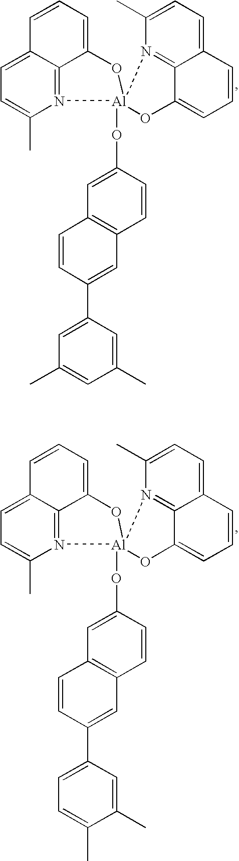

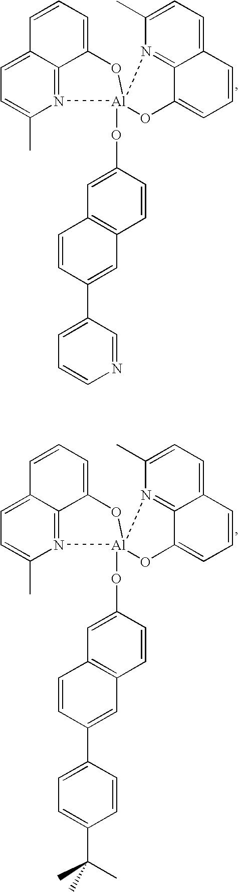

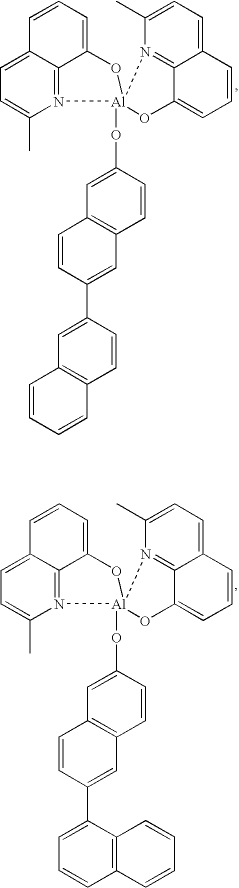

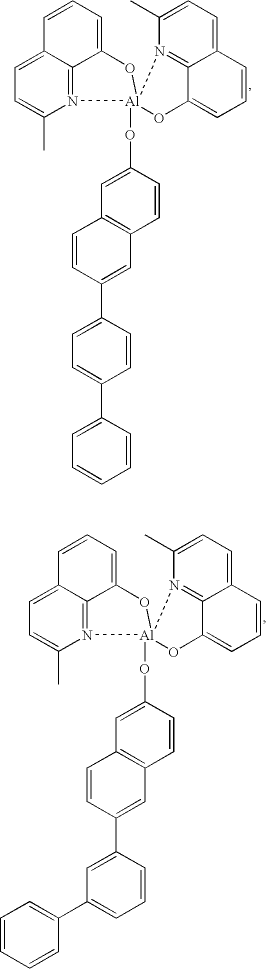

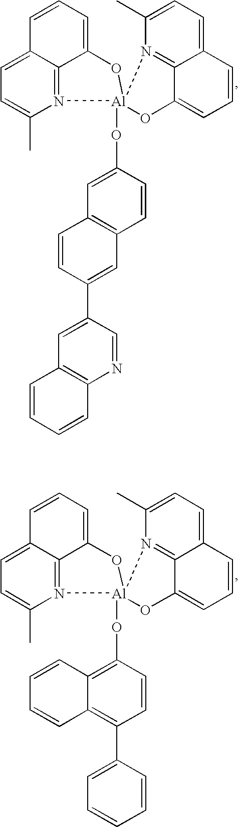

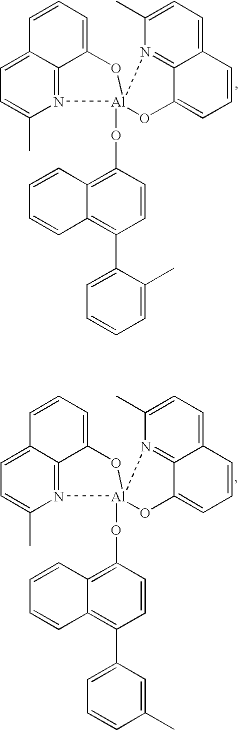

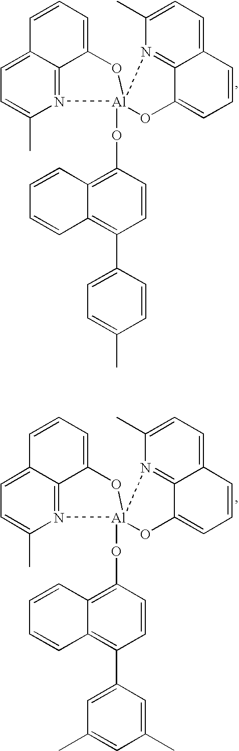

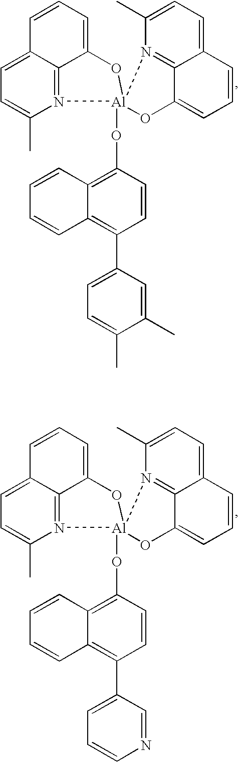

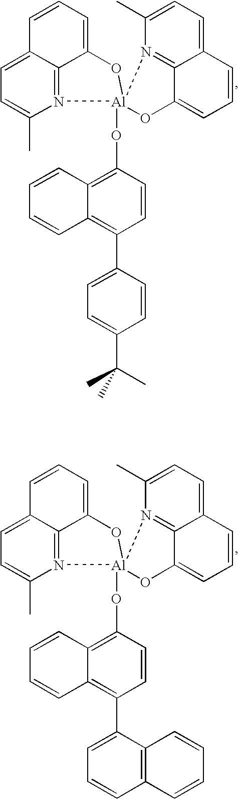

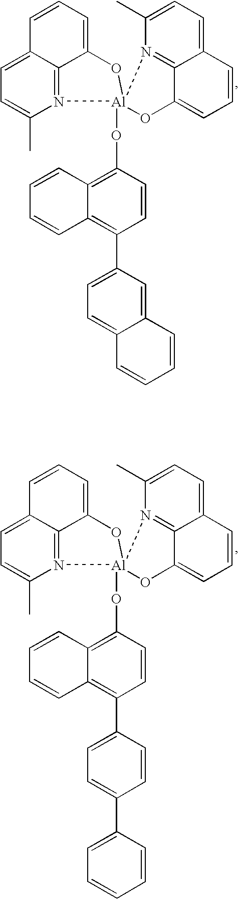

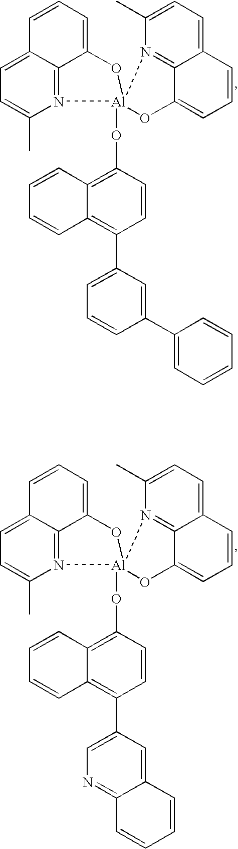

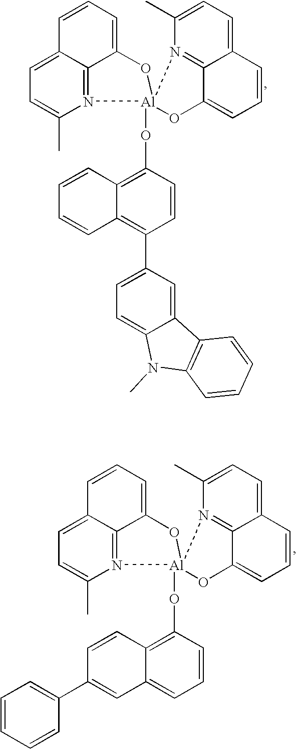

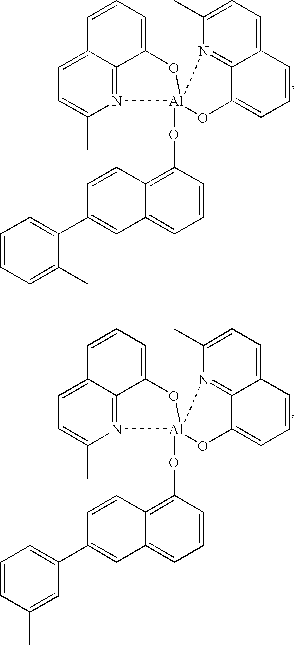

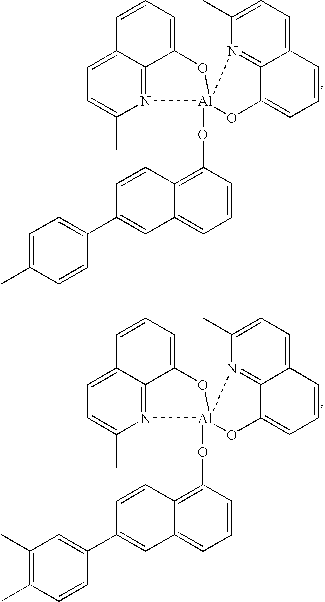

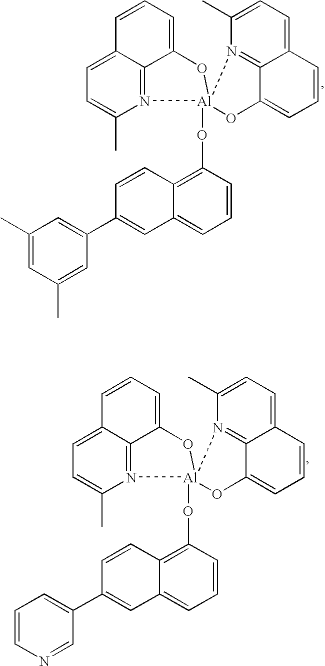

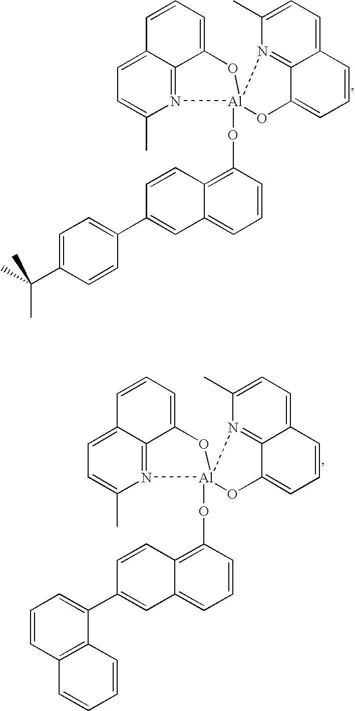

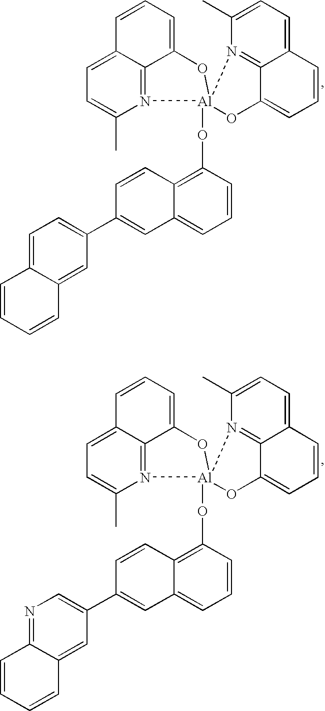

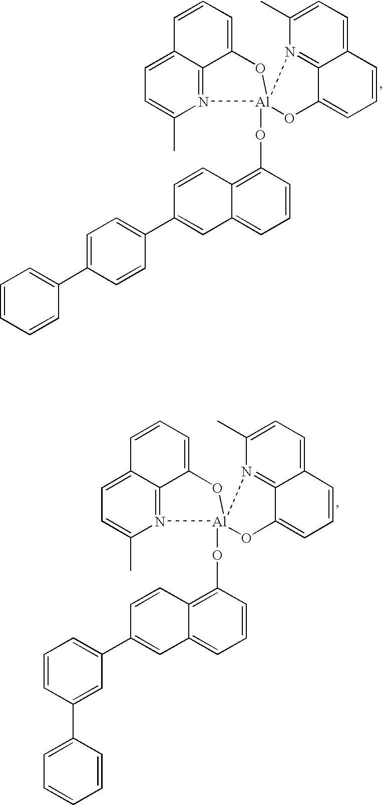

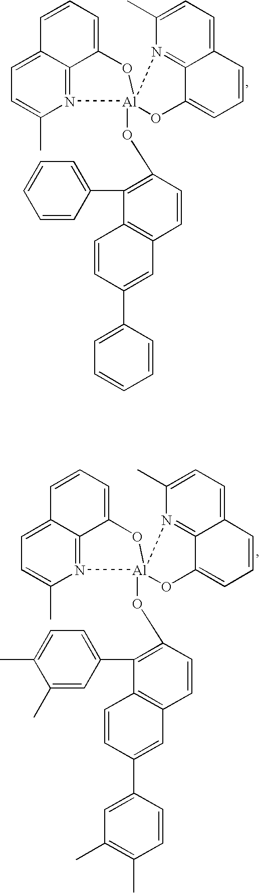

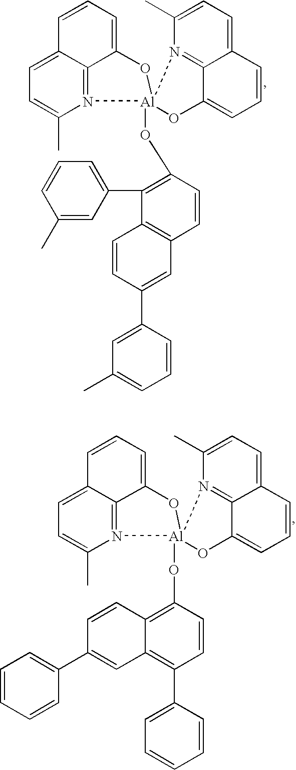

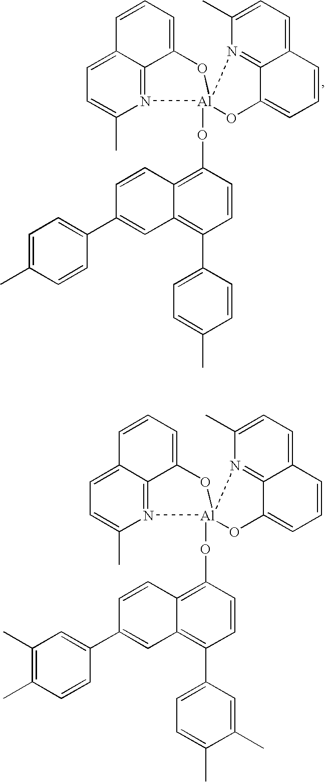

3. The organometallic complex according to claim 1, wherein the organometallic complex is selected from the group consisting of the following compounds:

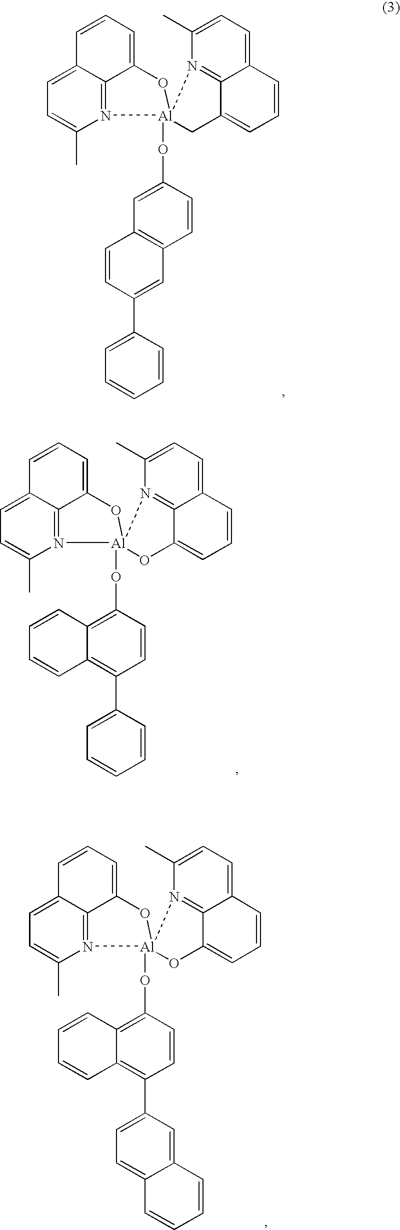

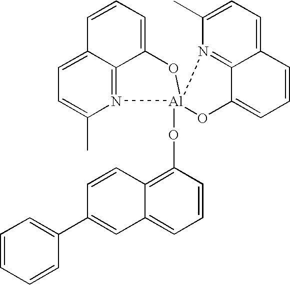

4. An organic light-emitting diode comprising an anode, an organic light-emitting layer and a cathode wherein the organic light-emitting layer includes the organometallic complex according to claim 1.

5. The organic light-emitting diode according to claim 4, wherein the organic light-emitting diode comprises an iridium complex as a dopant of the organic light-emitting layer.

6. The organic light-emitting diode according to claim 5, wherein the iridium complex is

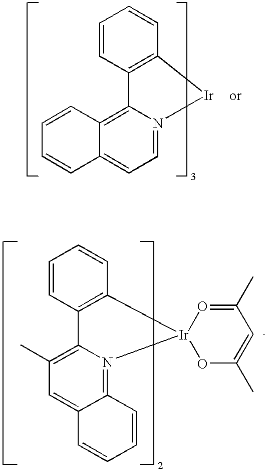

7. The organic light-emitting diode according to claim 5, wherein the dopant is used in an amount of 0.1 to 30% by weight of the organometallic complex.

8. The organic light-emitting diode according to claim 4, further comprising a hole transport layer disposed between the anode and the organic light-emitting layer, and an electron transport layer disposed between the cathode and the organic light-emitting layer.

9. The organic light-emitting diode according to claim 8, further comprising a hole injecting layer disposed under the hole transport layer.

10. The organic light-emitting diode according to claim 8, further comprising an electron injecting layer disposed on the electron transport layer.

11. The organic light-emitting diode according to claim 8, wherein the hole transport layer is formed of N,N′-bis(3-methylphenyl)-N,N′-diphenyl-[1,1′-biphenyl]-4,4′-diamine (TPD) or N,N′-di(naphthalen-1-yl)-N,N′-diphenyl-benzidine (α-NPD).

12. The organic light-emitting diode according to claim 9, wherein the hole injecting layer is formed of copper phthalocyanine (CuPc), 4,4′,4″-tri(N-carbazolyl)triphenylamine (TCTA) or 4,4′,4″-tris(3-methylphenylphenylamino)triphenylamine (m-MTDATA).
